(19) United States
(12) Patent Application Publication
(10) Pub. No.: US 2007/0285644 A1
(43) Pub. Date: Dec. 13, 2007

(54) Microlithographic Projection Exposure Apparatus

(75) Inventors: Markus Brotsack, Oberding (DE); Markus Deguenther, Aalen (DE); Wilhelm Ulrich, Aalen (DE); Joachim Wietzorrek, Jena (DE); Johannes Wangler, Koenigsbronn (DE); Heiko Feldmann, Aalen (DE); Andreas Zeiler, Offingen (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 11/575,042

(22) PCT Filed: Sep. 13, 2005
(86) PCT No.: PCT/EP05/09804

§ 371 Date: Aug. 8, 2007

Related U.S. Application Data
(60) Provisional application No. 60/609,398, filed on Sep. 13, 2004.
(60) Provisional application No. 60/609,397, filed on Sep. 13, 2004.
(60) Provisional application No. 60/684,888, filed on May 26, 2005.

(51) Int. Cl. G03F 7/20

(52) U.S. Cl. 355/67

(57) ABSTRACT

An illumination system for a microlithographic projection exposure apparatus comprises a masking device and a masking objective which projects the masking device onto an image plane. The illumination system further includes an optical correction element having a surface that is either aspherically shaped or supports diffractive structures that have at least substantially the effect of an aspherical surface. This surface is arranged at least approximately in a field plane which precedes the image plane of the masking objective The aspherically acting surface is designed such that a principal ray distribution generated by the illumination system in the image plane matches a principal ray distribution required by a projection objective.

### CROSS-REFERENCE TO RELATED APPLICATIONS

This application claims priority of U.S. provisional applications Ser. No. 60/609,397 and Ser. No. 60/609,398 both filed Sep. 13, 2004, and U.S. provisional application Ser. No. 60/684,888 filed May 26, 2005.

### BACKGROUND OF THE INVENTION

1. Field of the Invention

The invention relates to microlithographic projection exposure apparatus as are used in the manufacture of integrated circuits and other microstructured components. More particularly, the invention relates to illumination systems for such apparatus comprising an optical correction element having an aspherically shaped surface or a surface that has the effect of an aspherically shaped surface.

2. Description of Relevant Art

In the manufacture of highly-integrated electrical circuits and other microstructured components a plurality of structured layers is applied to a suitable substrate, which may be, for example, a silicon wafer. In order to structure the layers they are first covered with a photoresist which is sensitive to light of a given wavelength region, e.g. light in the deep ultraviolet (DUV) spectral region. The wafer coated in this way is then exposed in a projection illumination apparatus. A pattern of structures located on a mask is thereby imaged on the photoresist by means of a projection objective. Because the imaging scale is generally less than 1:1, such projection objectives are frequently referred to as reduction objectives.

After the photoresist has been developed the wafer is subjected to an etching or deposition process whereby the uppermost layer is structured according to the pattern on the mask. The remaining photoresist is then removed from the remaining parts of the layer. This process is repeated until all the layers have been applied to the wafer.

One of the primary objectives in developing the projection exposure apparatuses used in manufacture is the ability to define lithographically on the wafer structures of increasingly small dimensions. Small structures lead to high integration densities, which generally have a beneficial effect on the performance of the microstructured components manufactured by means of such apparatuses.

The size of the definable structures depends above all on the resolution of the projection objectives used. Because the resolution of the projection objective is inversely proportional to the wavelength of the projection light, one approach to increase the resolution is to use projection light having shorter and shorter wavelengths. The shortest wavelengths currently used are in the deep ultraviolet (DUV) spectral region and are of 193 nm and sometimes even 157 nm.

Another approach to increase the resolution is based on the idea of introducing an immersion liquid having a high refractive index into an immersion space located between a last lens of the projection objective on the image side and the photosensitive layer. Projection objectives which are designed for immersion operation, and are therefore also referred to as immersion objectives, can attain numerical apertures of more than 1, e.g. 1.3 or 1.4. In a broader sense one also refers to “immersion” if the photosensitive layer is covered by an immersion liquid without the last optical element of the projection objective on the image side necessarily being immersed in the immersion liquid.

Hitherto, projection objectives have usually been designed such that they are telecentric on both the object side and the image side. An imaging optical system is referred to as telecentric on the object side if the entrance pupil is located at infinity. The entrance pupil is the image of the aperture stop of the optical system formed on the object side. With regard to a principal ray distribution, this means that all the principal rays pass through the object plane parallel to the optical axis. The same applies correspondingly to telecentricity on the image side. Doubly-telecentric projection objectives are advantageous because imaging errors are reduced that arise if the mask and/or the wafer have small irregularities or are not positioned exactly in the object plane and the image plane, respectively.

However, with immersion objectives having very high numerical apertures of the kind possible with immersion operation it is difficult to achieve telecentricity on the object side. Such telecentricity requires very high-refraction lenses on the object side, which makes correction of Petzval imaging errors more difficult. For this reason such high-aperture projection objectives frequently have, at least on the object side, a principal ray distribution in which the principal rays are no longer disposed parallel to the optical axis in the object plane but are inclined thereto. If the tangent of the angle between the principal rays and the optical axis increases linearly with the distance from the optical axis, one speaks of a homocentric entrance pupil or of an optical system which is homocentric on the object side. Such high-aperture projection objectives are often, however, neither exact telecentrically nor exact homocentrically, but have more or less irregular principal ray distributions in the object plane.

A prerequisite for optimum imaging by the projection objective is that the principal ray distribution provided by the illumination system in the mask plane corresponds as exactly as possible to the object side principal ray distribution of the projection objective. Since the principle ray distribution of the projection objective cannot be significantly changed without altering the complete design of the objective, one usually attempts to adapt the principle ray distribution of the illumination system to the principle ray distribution of the projection objective, and not vice versa.

For describing principle ray distributions one often refers to the concept of pupil functions. This term denotes the distribution of the principle ray angles as a function of the field height in the image plane. The principle ray angle is formed in the image plane between the principle ray and a surface normal perpendicular to the image plane. Mathematically, the pupil function is described by a series expansion with odd powers; details can be found in U.S. Pat. No. 6,680,803 B2.

Often a masking objective is used to achieve a desired pupil function. The purpose of the masking objective of an illumination system is to image a diaphragm-like masking device onto an image plane of the masking objective in which the mask is arranged. The masking device has a plurality of blades, usually adjustable, that are imaged by the masking objective onto the mask. This ensures sharp edges of the region on the mask which is to be projected. Such a masking objective is sometimes referred to as a REMA objective, wherein REMA stands for “REticle MAsking”.

A combination of spherical lenses can be used to adjust pupil functions, as is widely known in the prior art. In order to reduce the number of spherical lenses required, U.S. Pat. No. 6,366,410 B1 proposes to replace a plurality of spherical lenses by at most five aspherical lenses, whose deviations from sphericity are comparatively small. In this way, the number of lenses required and the light path travelled in the lens material can be reduced by up to 60%.

Particularly simply constructed masking objectives with aspherical lenses are described in U.S. Pat. No. 6,680,803 B2 that has been mentioned above.

U.S. Pat. No. 4,906,080 A proposes to provide an aspherical lens in order to achieve the desired pupil function. Said lens is located directly before the mask plane. However, it has been found that such an arrangement of an aspherical surface degrades the imaging of the masking device seriously. To compensate for this degradation, further aspherical surfaces must be provided in the masking objective, which considerably increases the manufacturing cost of the illumination system.

EP 0 811 865 A2 discloses an illumination system for a microlithographic projection exposure apparatus in which an aspherical surface is arranged directly before a field plane in which a masking device for defining the shape of the field illuminated on the mask is arranged. In this case the aspherical surfaces are so defined that the numerical aperture of the illumination system is as constant as possible over the entire illuminated field.

EP 0 532 267 A1 discloses an objective for an infrared sensor, which comprises a first lens group for imaging an object plane onto an intermediate image plane and a second lens group, which images the intermediate image onto the detector plane or collimates it for observation through an eyepiece. The second lens group contains a diffractive optical element for the correction of imaging errors.

### SUMMARY OF THE INVENTION

It is therefore a first object of the present invention to provide a microlithographic exposure apparatus comprising an illumination system in which a principal ray distribution required by the projection objective is attained with few surfaces having an aspherical shape or having the effect of an aspherically shaped surface.

According to invention, this object is achieved by an illumination system which includes a light source for generating a projection light beam, a masking device, a masking objective that projects the masking device into an image plane and an optical correction element. The optical correction element includes at least one aspherically acting surface which is aspherically shaped or carries diffractive structures that have at least substantially the effect of an aspherically shaped surface. The at least one aspherically acting surface is arranged at least approximately in a field plane preceding the image plane of the illumination system. In addition, the aspherically acting surface is so designed that a principal ray distribution generated by the illumination system in the image plane approximates to an object side principal ray distribution of the projection objective. This principal ray distribution may be telecentric; however, the invention is particularly suitable for adjusting complex non-telecentric principal ray distributions.

The principal ray distribution generated by the illumination system approximates to the principal ray distribution required by the projection objective if the directions of corresponding principal rays deviate from one another by not more than 5° in the mask plane. Often it is preferable if the deviations are smaller than 2° or even 0.5°.

An arrangement of the aspherically acting surface at least approximately in a field plane preceding the mask plane enables this surface to be positioned considerably closer to a field plane. This in turn allows undesired degradation of the imaging of the masking device to be largely avoided. There is then no necessity to provide numerous additional aspherically acting surfaces which serve to compensate for the degradation.

The field plane in which the correction element is arranged is preferably located in front of the masking objective in the optical path of the projection light beam.

In this case it is simplest to arrange the aspherically acting surface in immediate proximity to and, in particular, immediately in front of the masking arrangement. Since the masking arrangement must in any case be arranged in immediate proximity to a field plane, there is no need to provide an additional field plane just for receiving the aspherically acting surface.

If a rod homogenizer is provided for mixing the light in the illumination system, it may in itself form the corrective element if its light exit surface constitutes the aspherically acting surface. Advantage is thereby taken of the fact that the light exit surface of the rod homogenizer forms a field plane.

In terms of production technology it is particularly simple if the correction element is optically contacted to a light exit surface of a rod homogenizer. Both the rod homogenizer and the correction element can then be produced in a manner known as such.

In another advantageous embodiment of the invention the masking objective forms the masking device with at most a small magnification, preferably with an imaging scale of 1:1 or less than 1:1. In this way a reduction of the angular demands placed on the correction element is achieved. The slopes which are to be provided on the aspherically acting surface of the correction elements can also be correspondingly smaller. This simplifies the manufacture of the correction element.

In a further embodiment the correction element forms part of a field lens group in the entrance pupil of which an optical raster element is arranged and the focal plane of which is the field plane.

In an particularly advantageous embodiment a further correction element is provided, which also has at least one aspherically acting surface which is aspherically shaped or carries diffractive structures that have at least substantially the effect of an aspherically shaped surface, the further correction element being arranged inside the masking objective and being so designed that the principal ray distribution generated in the image plane by the illumination system further approximates to an object side principal ray distribution required by the projection objective.

In this way two correction elements arranged close to a field plane are provided having superposing optical effects with respect to the principal ray distribution. This distribution of the adjustment of the principal ray distribution on two aspherically acting surfaces which are arranged in or in the vicinity of different field planes allows even very complex principal ray distributions to be adjusted without the need for the two aspherically acting surfaces of the correction elements to have a particularly complicated shape. This simplifies the production of these surfaces and therefore has cost advantages. The aspherically acting surface which is closest to a field plane should then make the greatest contribution to the adjustment of the principal ray distribution. The precise allocation of these contributions to the two aspherically acting lenses may be determined, for example, by means of a numerical optimization method.

However, limits are also placed on the use of aspherical lenses in masking objectives. Aspherical lenses do admittedly offer more freedom for the design of the objective, compared with spherical lenses. Nevertheless, in particular for reasons of fabrication technology, aspherical lenses are also subject to limitations with respect to the surface contour and maximum possible arrow height. The large production costs are a substantial disadvantage of aspherical lenses.

It is therefore a further object of the present invention to provide an illumination system with a masking objective which is constructed more simply and is more cost-effective to produce.

This further object is achieved in that the masking objective contains at least one diffractive optical element.

The invention is based on the discovery that diffractive optical elements can achieve effects which otherwise can be produced only with aspherical lenses. Diffractive optical elements, moreover, generally require less space than aspherical lenses and are often more cost-effective to produce. Diffractive optical elements can be produced in a particularly space-saving way when they do not have their own support with a flat or curved support surface, but are fabricated on a surface of a lens that is required anyway.

The special properties of diffractive optical elements become advantageous particularly when the masking objective is also being used to adjust a particular pupil function. This is because diffractive optical elements offer significantly more design freedom compared with aspherical lenses, since they are not subject to limitations with respect to arrow height and testability. With diffractive element optical elements, therefore, a desired pupil function can be adjusted more accurately than has so far been possible with spherical lenses or even aspherical lenses. This in turn has a positive effect on the imaging properties and, in particular, the telecentricity properties of the projection objective.

The use of at least one diffractive optical element furthermore has the advantage that quantities other than the pupil function can be adjusted effectively by simple means. Examples for such other quantities are the angular distribution of the coma rays, the uniformity of the intensity distribution in the mask plane, the ellipticity of the illumination and quality with which a desired angular distribution is produced in the mask plane. With diffractive optical elements, furthermore, chromatic imaging errors can be corrected in a straightforward way since conventional lens materials and diffractive optical elements differ in terms of the sign of the dispersion.

With a view to adjusting the pupil function, it would be ideal to arrange a diffractive optical element in the image plane of the masking objective, since only the angular distribution, i.e. the pupil function, of the principle rays would then be influenced. However, since the mask is arranged in the image plane of the masking objective during the projection operation, a diffractive optical element cannot be placed there.

A conceivable position for arranging a diffractive optical element may then, for example, be a conjugate field plane preceding the image plane of the masking objective. The arrangement of aspherically acting surfaces in a field planes preceding the image plane has been described in detail further above.

If such a preceding field plane does not exist, then it is favorable to arrange a diffractive optical element as close as possible to the field plane. This may be achieved, for example, if the at least one diffractive optical element is the last optical element on the image side of the masking objective.

If the masking objective contains a plurality of lens groups, then, for the aforementioned reasons, it is advantageous if the at least one diffractive optical element is arranged in a field lens group which is arranged closest to the image plane.

The masking objective may be constructed particularly compact and cost-effective if the field lens group contains only refractive optical elements with spherical surfaces and a plurality of diffractive optical elements. In this way, the effect of previously used aspherical lenses is fully achieved by combining a plurality of diffractive optical elements. In order to obtain an additional degree of design freedom, the masking objective may contain at least one optical element with an aspherical refractive surface arranged in front of a diaphragm plane of the masking objective.

The diffraction efficiency of the at least one diffractive optical element has a special importance for the function of the masking objective. Low diffraction efficiencies lead not only to a light loss, but also perturb the illumination of the mask arranged in the image plane. In fact, on the basis of the preferred arrangement of the diffractive optical element in the vicinity of the field plane (mask plane), a larger part of the light scattered into undesired diffraction orders will reach the mask. This can lead to the creation of undesired additional images.

For these reasons, it is advantageous for the at least one diffractive optical element to be designed so that it deviates light only through small angles, and preferably by less than 2°, more preferably less than 1°. The at least one diffractive optical element may then have larger grating periods, so that blazed diffraction structures can be approximated more easily by a multiplicity of steps. Generally, the better this approximation is the greater the diffraction efficiency will be.

It is furthermore advantageous for the diffractive optical element to be designed so that light is predominantly diffracted into the first diffraction order. In general, the diffraction efficiency is then greater than when higher diffraction orders are used.

For at least one principle ray, in another advantageous embodiment of the invention, at least a first diffractive optical element leads to an increase in the principle ray angle and a second diffractive optical element leads to a decrease in the principle ray angle. The two diffractive optical elements therefore have opposite effects, although the overall effect of the two diffractive optical elements may lead to an increase or a decrease in the principle ray angle according to the way in which it is designed with a view to the desired pupil function. Here, the result of the partial compensation is that telecentricity deviations of the coma rays, which would occur in the case of only one large-aperture diffractive optical element, are substantially corrected.

In this case the first diffractive optical element and the second diffractive optical element may be arranged in a portion of the masking objective between a pupil plane and the image plane. This is advantageous because, if the diffractive optical element were to be arranged in front of a diaphragm plane, the diaphragm itself would have a field-dependent effect which is generally undesired.

### BRIEF DESCRIPTION OF THE DRAWINGS

Various features and advantages of the present invention may be more readily understood with reference to the following detailed description taken in conjunction with the accompanying drawing in which:

FIG. 1 shows a projection exposure apparatus in a schematized side view which is not to scale;

FIG. 2 shows, in a simplified meridional section which is not to scale, essential components of an illumination system of the projection exposure apparatus shown in FIG. 1 according to a first embodiment;

FIG. 3 shows a detail of the illumination system shown in FIG. 2 in which a rod homogenizer forms a correction element having a light exit surface which is aspherically shaped;

FIG. 4 shows a detail of the illumination system shown in FIG. 2 in which a rod homogenizer forms a correction element carrying diffractive structures that have the effect of an aspherically shaped surface;

FIG. 5 shows a detail of an illumination system corresponding to FIG. 3 in which, according to a further embodiment of the invention, a correction element having an aspherically shaped surface is received in a mount;

FIG. 6 is a representation corresponding to FIG. 2 of an illumination system according to a further embodiment of the invention, comprising two correction elements;

FIG. 7 shows a meridional section through an illumination system according to still another embodiment, comprising a diffractive optical element in a masking objective;

FIG. 8 is an enlarged view of the field lens group of the masking objective containing the diffractive optical element;

FIG. 9 shows a detail of the diffractive optical element shown in FIG. 8 in an enlarged longitudinal section;

FIG. 10 shows a radial line density distribution of the diffractive optical element shown in FIG. 9;

FIG. 11 shows another exemplary embodiment of a field lens group of a masking objective containing three diffractive optical elements.

### DETAILED DESCRIPTION OF PREFERRED EMBODIMENTS

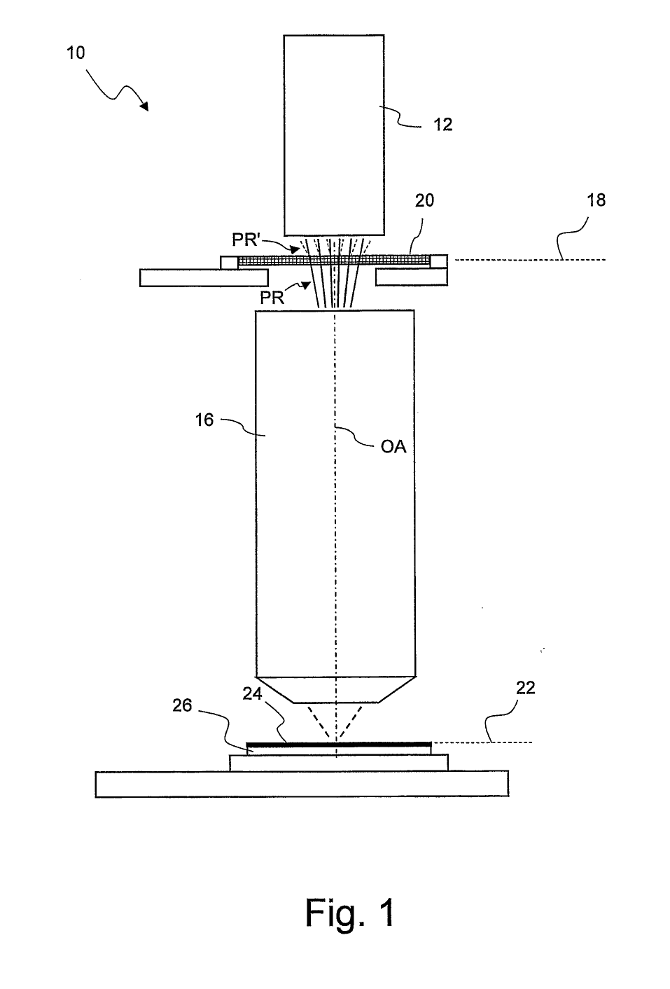

FIG. 1 shows a projection exposure apparatus denoted in its entirety by 10 in a meridional section which is simplified and is not to scale. The projection exposure apparatus 10 comprises an illumination system 12 which is used to generate a projection light beam. The projection exposure apparatus 10 further comprises a projection objective 16 having an object plane 18 in which a mask 20 may be arranged. Located in an image plane 22 of the projection objective 16 is a photosensitive layer 24 applied to a substrate 26 which may be, for example, a silicon wafer.

A beam of principal rays of the projection objective 16 is indicated in FIG. 1 by PR. Because the projection objective 16 is not telecentric on the object side, i.e. in the direction of the mask 20, but is approximately homocentric instead, the principal rays PR do not run parallel to the optical axis OA of the projection objective, but are inclined thereto. For obtaining optimum imaging properties, the principal ray distribution provided by the illumination system 12 in the object plane of the projection objective 16 should match as closely as possible the object side principal ray distribution of the projection objective 16. As will become apparent below, the illumination system 12 is designed such that this condition is fulfilled. In FIG. 1 a principal ray distribution, as generated by an illumination system 12 which is not corrected with respect to principal ray distribution, is indicated in an exemplary manner by broken lines PR′. In this case the angles between the principal ray directions indicated by broken lines and the principal ray directions indicated by continuous lines are greater than 5°.

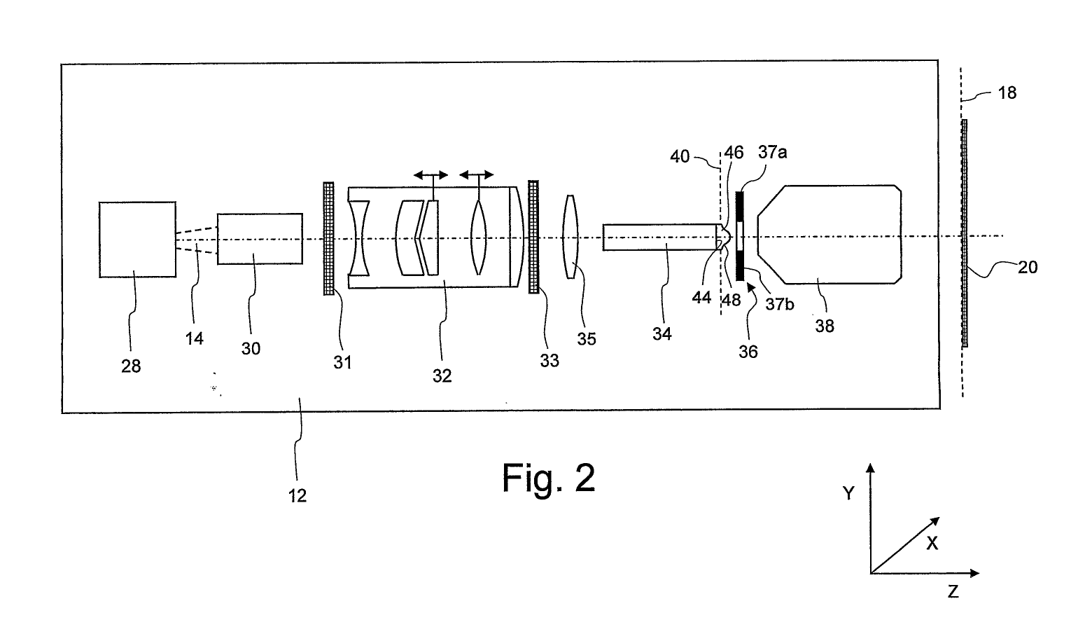

FIG. 2 shows details of the illumination system 12 in a highly schematic representation. The illumination system 12 comprises a light source 28 which may be, for example, an excimer laser. The projection light beam generated by the light source 28 first passes through a beam shaping device 30, a first optical raster element 31, a zoom-axicon objective 32 for setting different illumination angle distributions, a second optical raster element 33, a condenser lens 35 and a rod homogenizer 34 which mixes and homogenizes the projection light beam. An adjustable masking device 36, which influences the geometry of a light field illuminating the mask 20, is arranged immediately behind the rod homogenizer 34 in the light propagation direction. For this purpose the masking device 36 includes two pairs of opposed blades arranged at right angles to one another, of which only the blades disposed in the Y direction can be seen in FIG. 2 and are denoted by 37a, 37b.

The illumination system 12 further comprises a masking objective 38 having an object plane 40 and an image plane that coincides with the object plane 18 of the projection objective 16. In or close to the object plane 40 of the masking objective 38 the light exit surface 44 of the rod homogenizer 34 is located. Because the masking device 36 is located in or in immediate proximity to the object plane 40 of the masking objective 38, it is imaged by the masking objective 38 onto the mask 20 and thereby ensures a sharp delimitation of the region illuminated on the mask 20. To this extent the illumination system is known in the art, see, for example, U.S. Pat. No. 6,285,443 A.

A refractive correction element 46 having an aspherically shaped surface 48 is arranged in the object plane 40 of the masking objective 38 and optically contacted to the light exit surface 44 of the rod homogenizer 34. The aspherically shaped surface 48 is therefore located in immediate proximity to a field plane, namely the object plane 40 of the masking objective 38. The shape of the aspherical surface 48 is adapted to the object side principal ray distribution of the projection objective 16. The calculation of such aspherically shaped surfaces is known as such in the art, see, for example, U.S. Pat. No. 4,906,080 A that has been mentioned at the outset. Therefore further details relating to such calculations need not be described.

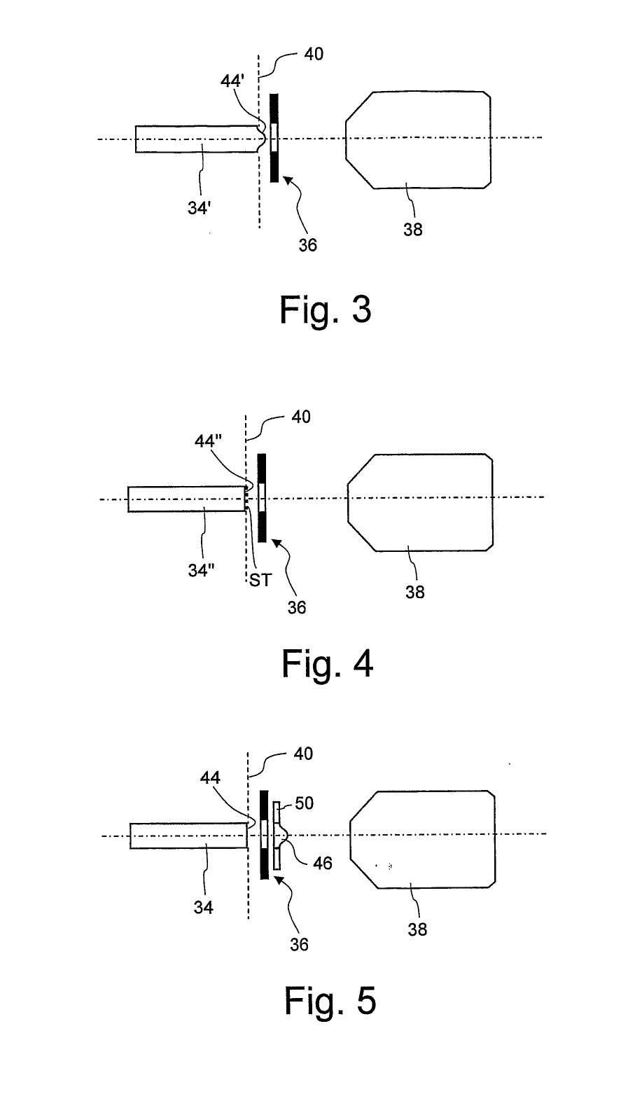

FIGS. 3 to 5 show further embodiments how an aspherically shaped surface may be arranged in the illumination system 12 in or close to a field plane preceding the object plane 18 of the projection objective 16.

In the embodiment shown in FIG. 3 the rod homogenizer 34′ itself forms the correction element, since its light exit surface 44′ has the required aspherical shape.

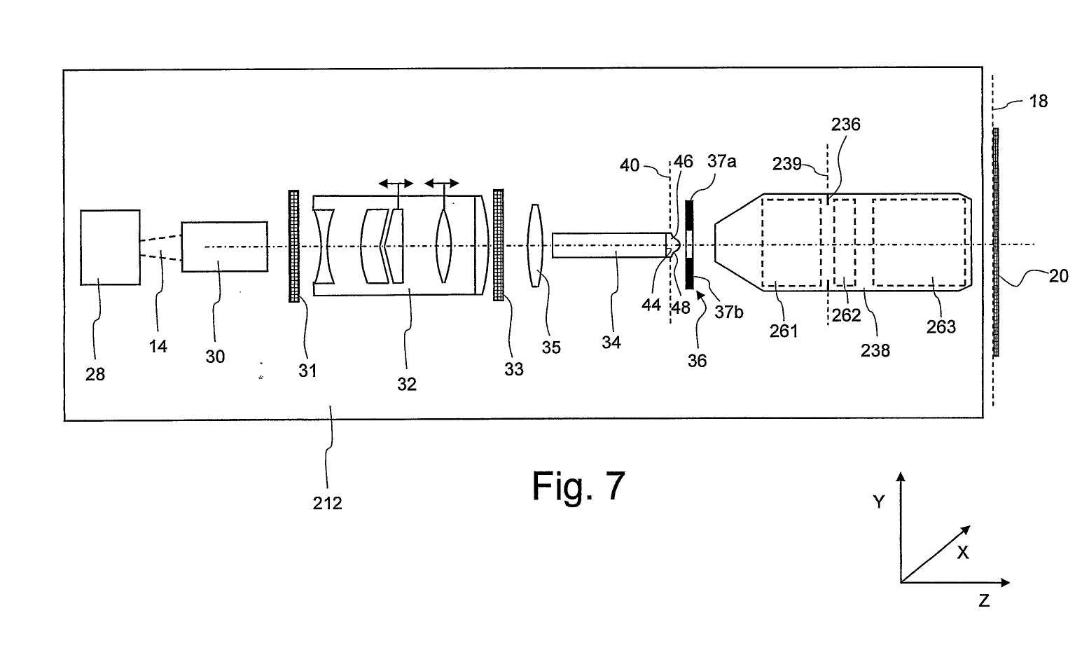

In the embodiment shown in FIG. 4, the rod homogenizer 34″ also forms the correction element. However, its light exit surface 44″ does not have an aspherical shape but carries diffractive structures ST which have the effect of an aspherical surface. Further details on the use of such diffractive structures are described below with reference to the embodiments shown in FIGS. 7 to 11.

In the embodiment shown in FIG. 5, the correction element 46 is not optically contacted to the light exit surface 44 of the rod homogenizer 34, but is held in a mount 50. The mount 50 with the correction element 46 is arranged immediately behind the masking device 36 (if seen in the light propagation direction) and therefore is still in the vicinity of the field plane 40.

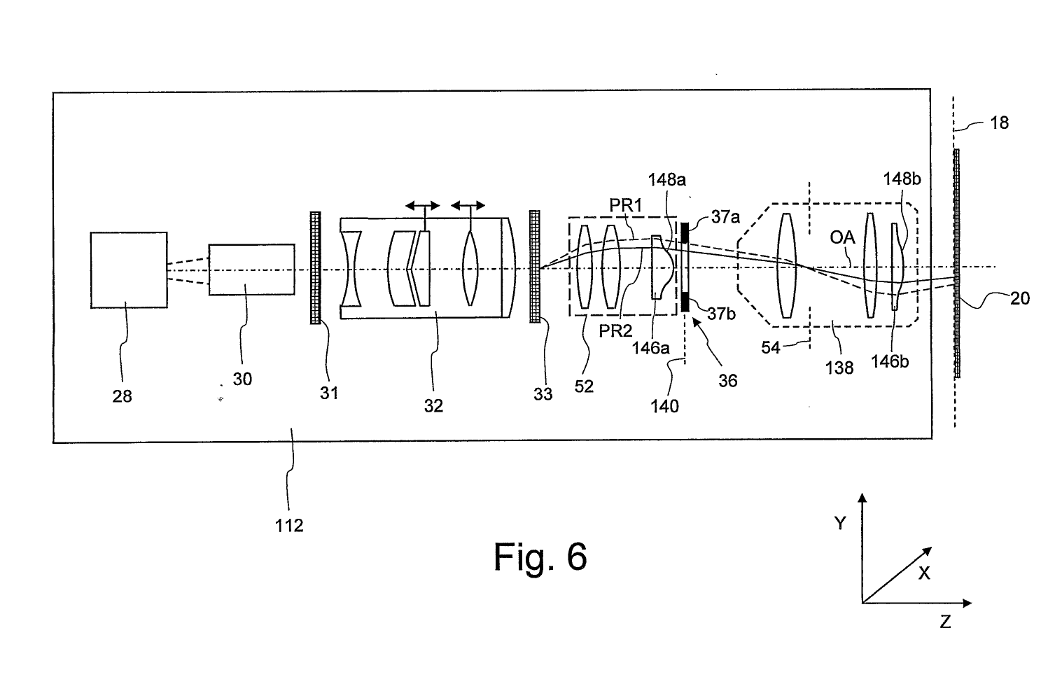

FIG. 6 shows a further embodiment of an illumination system which is denoted in its entirety by 112. The condenser lens 35 and the rod homogenizer 34 of the embodiment shown in FIG. 2 are now replaced by a more complex condenser lens group 52 having an entrance pupil in which the second optical raster element 33 is arranged. The image plane of the condenser lens group 52 is the object plane 140 of a masking objective 138. The masking device 36 with the blades 37a, 37b is arranged in this field plane, as in the embodiment shown in FIG. 2.

Immediately before the field plane 140, the field lens group 52 contains a first correction element 146a with a surface 148a facing towards the field plane 140 that is aspherically curved. A second correction element 146b is located in the masking objective 138 and has an aspherically curved surface 148b, too. This aspherical surface 148b is the last curved surface of the illumination system 112 before the image plane 18.

In FIG. 6 two principal rays PR1, PR2 intersect the optical axis OA of the illumination system 112 in a pupil plane 54, in which an aperture stop may be located. The aspherical surfaces 148a, 148b of the correction elements 146a, 146b change the direction of the two principal rays PR1, PR2 in such a way that the principal ray distribution coincides at least substantially with the principal ray distribution of the following projection objective 16 in the image plane 18. The coincidence is such that the directions of corresponding principal rays deviate from one another by not more than 5°, preferably by not more than 2°, more preferably by not more than 0.5°, in the image plane 18.

FIG. 7 shows another embodiment of an illumination system 212 which in a representation similar to FIG. 2. The masking objective 238 contains three lens groups 261, 262 and 263, as is known from U.S. Pat. No. 5,982,558 A. A diaphragm 236 is arranged in a pupil plane 239 between the first lens group 261 and the second lens group 262.

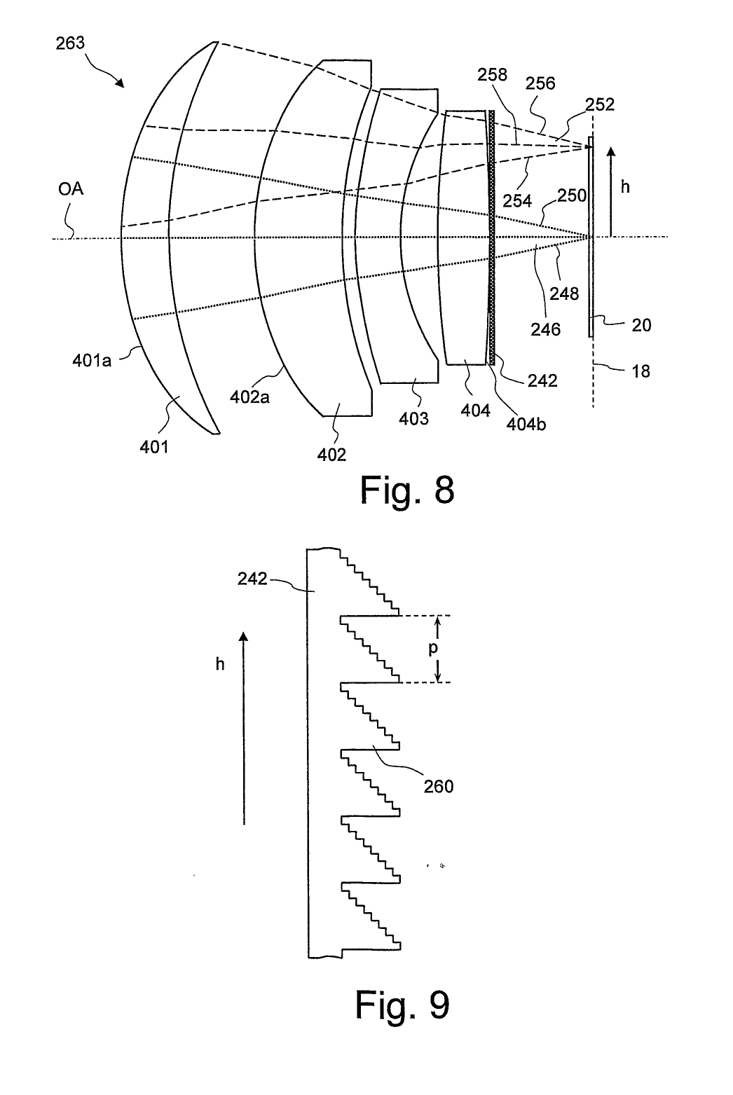

FIG. 8 shows the third lens group 263 in an enlarged meridional section. The lens group 263, which will be referred to below as the field lens group because of its proximity to the field plane 232, comprises four lenses 401, 402, 403, 404 and a diffractive optical element 242. The surface 401a of the lens 401 and the surface 402a of the lens 402 are aspherical surfaces in this exemplary embodiment, whereas the other lens surfaces of the field lens group 262 are spherical.

In FIG. 8 two light bundles are shown, namely a coaxial light bundle 246 with marginal rays 248 and 250 and a marginal light bundle 252 with a lower marginal ray 254, an upper marginal ray 256 and a principal ray 258. The principal ray 258 of the marginal light bundle 252 is the principle ray with the greatest field height h above the optical axis OA. The principle ray 258 intersects the image plane 232 with a principle ray angle of approximately 90°. The dependency of the principle ray angle on the field height h establishes the pupil function of the masking objective 238.

The purpose of the diffractive optical element 242 is to modify the pupil function of the masking objective 238 so that an optimal pupil function is provided for the subsequent projection objective 16. Which pupil function is optimal for the projection objective 16 depends on the design details of the projection objective. Often a telecentric pupil function is preferred, but sometimes a more or less homocentric pupil function is required by the projection objective 16.

It should be understood that the pupil function is not determined exclusively by the diffractive optical element 242, but by the interaction of a plurality of optical elements. In particular, the aspherical surfaces 401a, 402a allow additional design freedom for adjusting the desired pupil function.

In order to be able to influence exclusively the principle rays, it would be optimal to arrange the diffractive optical element 242 in the object plane 18 of the projection objective 16. However, this position is required for the mask 20. Nevertheless the diffractive optical element 242 is the last curved optical element on the image side of the masking objective 238 and is thus arranged as close as possible to the object plane 18. As a result of this position, the light bundles 246, 252 converging towards the mask 20 have a small diameter such that the effect of the diffractive optical element 242 on the marginal rays 248, 250 and the upper and lower marginal rays 256 and 254 is small.

FIG. 9 shows a detail of the diffractive optical element 242 as shown in FIG. 8 in an enlarged longitudinal section. The diffractive optical element 242 is designed as a phase grating in this exemplary embodiment, and has a multiplicity of blazed diffraction structures 260 periodically arranged in the radial direction, the grating period being denoted by p in FIG. 9. Each diffraction structure 260 has the shape of a right-angled triangle in cross section. The hypotenuse of this triangle is not continuous but stepped eight times in order to simplify the production process. The diffraction structures 260 may be inclined with respect to the base surface in order to achieve a higher diffraction efficiency.

Instead of phase gratings with eight steps, for example, it is also possible to use gratings with another number of steps. Any increase in the number of steps generally increases the diffraction efficiency. For example, increasing the number of steps from 8 to 16 leads to a rise in the diffraction efficiency from about 96% to about 99%. Owing to their high diffraction efficiency, phase gratings with a continuous profile (so-called grey level gratings) are particularly suitable, as described for example in an article by Michael R. Wang et al. entitled “Laser direct-write gray-level mask and one-step etching for diffractive microlens fabrication”, Applied Optics, Vol. 37, No. 32, pages 7568 to 7576. In general, coatings also have a favourable effect on the diffraction efficiency.

Besides phase gratings, it is also conceivable to use diffractive optical elements which affect the intensity rather than the phase of electromagnetic waves passing through them.

Since the diffractive optical element 242 may have a diameter of about 15 cm or more, it sometimes cannot be readily produced by lithographic means. Production using a laser plotter which writes directly on a quartz plate may be envisaged as an alternative. Such a laser plotter can also be used to produce grey level gratings.

It is also conceivable to produce the diffractive optical element with the aid of an electron beam scriber, for example as available from the company LEICA. Structure sizes of less than 100 nanometres can be defined in this way. Diffractive optical elements with large areas can furthermore be produced holographically.

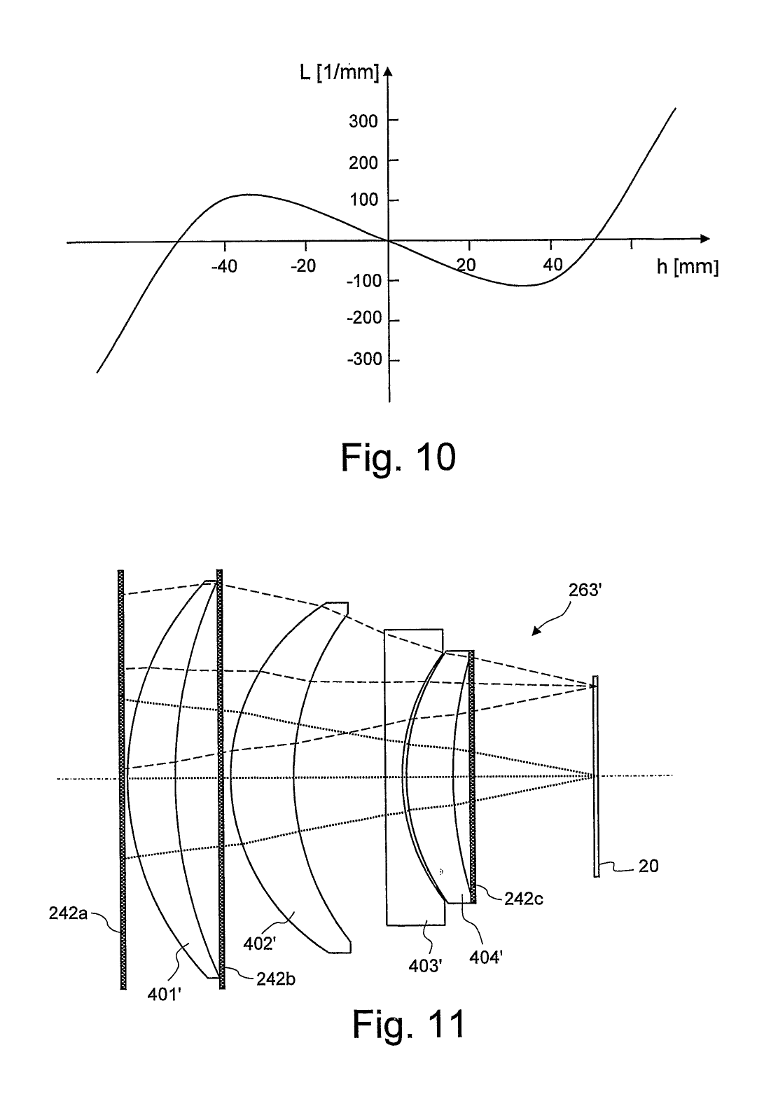

FIG. 10 is a graph showing the dependency of the line density L, which is equal to the inverse of the period p, on the field height h (radial direction). It can be seen in the FIG. 10 that the line density L rises steeply for field heights h beyond about 50 mm, whereas it is less than 100 lines per mm for smaller field heights. In this case, a negative sign of the line densities indicates that the diffractive optical element 15 inverts the direction of transmitted principle rays relative to the optical axis. Specifically this means that, for positive and negative field heights, principle rays which pass through the diffractive optical element 15 in the region with negative line densities will respectively travel divergently or convergently with respect to the optical axis.

In the exemplary embodiment shown in FIG. 11, the field lens group 262′ has only lenses 401′ to 404′ with spherical surfaces. In order to compensate for this, the field lens group 263′ contains a total of three diffractive optical elements 242a, 242b and 242c which are designed so as to adjust the desired pupil function. Aspherical lenses are not necessary in this exemplary embodiment.

Besides saving on costs, the use of a plurality of diffractive optical elements 242a, 242b, 242c in the field lens group 263′ also has the advantage that a substantial independence from the illumination setting adjusted for the illumination system can be achieved in this way. The interaction of a plurality of diffractive optical elements and/or aspherical surfaces allows better correction of the entire pupil for each field point. With a single diffractive optical element, conversely, the principle ray angle can be adjusted only for a particular predetermined illumination setting. For other illumination settings, a deviation from the desired pupil function, leading for example to a telecentricity error at the exit of the projection objective, can be avoided only with difficulty.

The diffractive optical elements 242a, 242b, 242c are designed so that the diffractive optical element 242a leads to an increase in the principle ray angle, and the diffractive optical elements 242b, 242c lead to a decrease in the principle ray angle. As a result, the effects of the diffractive optical elements 242a, 242b, 242c partially compensate. Telecentricity deviations of the coma rays, which would occur in the case of only one large-aperture diffractive optical element, are therefore corrected at least partially.

In the exemplary embodiments presented above, the diffractive optical elements 242, 242a, 242b, 242c are applied on plane plates. However, it is also conceivable to apply the diffraction structures directly on curved surfaces, for example on the surface 404b of the last field lens 404 on the image side in the field lens group 263 shown in FIG. 8.

1. A microlithographic projection exposure apparatus, comprising:
a) a projection objective and
b) an illumination system, comprising
a light source capable of generating a projection light beam,
a masking device,
a masking objective which is capable of imaging the masking device into an image plane, and an
optical correction element having at least one aspherically acting surface which is
aspherically shaped or carries diffractive structures that have at least substantially the effect of an aspherically shaped surface,
arranged at least approximately in a field plane preceding the image plane of the masking objective, and
designed such that a principal ray distribution generated by the illumination system in the image plane approximates to an object side principal ray distribution of the projection objective.

2. The apparatus according to claim 1, wherein the field plane is the object plane of the masking objective.

3. The apparatus according to claim 2, wherein the at least one aspherically acting surface is arranged in immediate proximity to the masking device.

4. The apparatus according to claim 3, wherein the at least one aspherically acting surface is arranged immediately in front of the masking device in the optical path of the projection light beam.

5. The apparatus according to claim 4, wherein the correction element is a rod homogenizer having a light exit surface, which constitutes the at least one aspherically acting surface.

6. The apparatus according to claim 4, comprising a rod homogenizer having a light exit surface, to which the correction element is optically contacted.

7. The apparatus according to claim 2, wherein the masking objective projects the masking device with an imaging scale equal to or less than 1:1.

8. The apparatus according to claim 1, wherein the correction element is contained in a field lens group having an entrance pupil, in which an optical raster element is arranged, and an image plane which coincides with the field plane.

9. The apparatus according to claim 1, comprising a further correction element which also has at least one aspherically acting surface which is aspherically shaped or carries diffractive structures that have at least substantially the effect of an aspherically shaped surface, the further correction element being arranged inside the masking objective and being designed such that the principal ray distribution generated by the illumination system in the image plane further approximates to the object side principal ray distribution of the projection objective.

10. The apparatus according to claim 9, wherein the further correction element is the last or penultimate optical element of the masking objective if viewed along a beam propagation direction.

11. Apparatus according to claim 1, wherein the object side principal ray distribution of the projection objective (16) is non-telecentric.

12. The apparatus according to claim 1, wherein the principal ray distribution generated by the illumination system in the image plane is so approximated to the object side principal ray distribution of the projection objective that the directions of corresponding principal rays deviate from one another by not more than 5°in the image plane.

13. The apparatus according to claim 1, wherein the masking objective comprises at least 10 spherical lenses.

14. The apparatus according to claim 1, wherein the masking objective comprises at least 7 spherical lenses and at least one aspherical lens.

15. A method for adapting an illumination system of a microlithographic projection exposure apparatus to a projection objective, comprising the following steps:
a) providing an illumination system comprising
a light source generating a projection light beam,
a masking device,
a masking objective which images the masking device into an image plane, and an optical correction element having at least one aspherically acting surface which is aspherically shaped or carries diffractive structures (ST) that have at least substantially the effect of an aspherically shaped surface, the at least one aspherically acting surface
arranged at least approximately in a field plane preceding the image plane of the illumination system;
b) defining the aspherically acting surface in such a way that a principal ray distribution generated by the illumination system in the image plane approximates to an object side principal ray distribution of the projection objective.

16. A method according to claim 15, wherein the principal ray distribution generated by the illumination system in the image plane is so approximated to the object side principal ray distribution of the projection objective that the directions of corresponding principal rays deviate from one another by not more than 5°, in the image plane.

17. A method for the microlithographic production of microstructured components, comprising the following steps:
a) providing a support on to at least a part of which a layer of a photosensitive material is applied;
b) providing a mask containing structures to be projected;
c) generating a projection light beam in an illumination system in which a masking objective images projects a masking device into an image plane;
d) projecting at least a part of the mask on to a region on the layer by means of a projection objective,
wherein
the projection light beam passes through an optical correction element having at least one aspherically acting surface which is
aspherically shaped or carries diffractive structures that have at least substantially the effect of an aspherical surface,
arranged in a field plane preceding the image plane of the illumination system and is
so designed that a principal ray distribution generated by the illumination system in the image plane approximates to an object side principal ray distribution of the projection objective.

18. An illumination system of a microlithographic projection exposure apparatus, comprising a masking objective which has an object plane and an image plane and contains at least one diffractive optical element, and
a masking device arranged in the object plane of the masking objective.

19. The illumination system according to claim 18, wherein the at least one diffractive optical element is the last optical element on the image side of the masking objective.

20. The illumination system according to claim 18, wherein the masking objective contains a plurality of lens groups, and wherein the at least one diffractive optical element is arranged in a field lens group which is as close as possible to the image plane.

21. The illumination system according to claim 20, wherein the field lens group contains only refractive optical elements with spherical surfaces and a plurality of diffractive optical elements.

22. The illumination system according to claim 21, wherein masking objective contains at least one optical element with an aspherical refractive surface arranged in front of a diaphragm plane of the masking objective.

23. The illumination system according to any of claims 18, wherein the at least one diffractive optical element deviates light by less than 2°.

24. The illumination system according to any of claims 18 wherein for at least one principle ray, a first diffractive optical element increases an angle formed between the principle ray and an optical axis of the masking objective, and a second diffractive optical element decreases the angle formed between the principle ray and the optical axis.

25. The illumination system according to any of claims 18, wherein the first diffractive optical element and the second diffractive optical element are arranged in a portion of the masking objective between a pupil plane and the image plane.

26. A method for the microlithographic production of microstructured components, comprising the following steps:
a) providing a support supporting a layer made of a photosensitive material;
b) providing a mask containing structures to be imaged;
c) generating a projection light beam in an illumination system in which a masking objective having at least one diffractive optical element images a masking device arranged in an object plane of the masking objective onto an image plane;
d) projecting at least a part of the mask onto a region on the layer using the projection light beam.
